(19) United States
(12) Patent Application Publication
(10) Pub. No.: US 2021/0182065 A1
(43) Pub. Date: Jun. 17, 2021

(54) APPARATUSES AND METHODS FOR IN-LINE NO OPERATION REPEAT COMMANDS

(71) Applicant: MICRON TECHNOLOGY, INC., BOISE, ID (US)

(72) Inventors: Chikara Kondo, Sagamihara (JP); Roman A. Royer, Boise, ID (US)

(73) Assignee: MICRON TECHNOLOGY, INC., BOISE, ID (US)

(21) Appl. No.: 16/715,416

(22) Filed: Dec. 16, 2019

(51) Int. Cl. G06F 9/30; G06F 9/38; G06F 13/16

(52) U.S. Cl. CPC G06F 9/30076; H01L 25/18; G06F 13/1689; G06F 9/3853

(57) ABSTRACT

Embodiments of the disclosure are drawn to apparatuses, systems, and methods for in-line no operation (NOP) repeat commands. An algorithmic pattern generator (APG) may be loaded with a set of instructions. A line of the instructions may include an active command and an NOP repeat command. The active command may be a command to be provided by the APG when the line of instruction is executed. The NOP repeat command may be a value which indicates a number of times that an NOP command should be issued after the active command when the line of instruction is executed. The APG may include an NOP controller circuit (and/or phase controller circuit) which determines when the next active command should be provided based, in part, on a count of the number of times that an NOP command is issued.

### BACKGROUND

This disclosure relates generally to semiconductor devices, such as semiconductor memory devices. The semiconductor device may include a variety of circuits, and may generally receive instructions loaded from outside of the semiconductor device. These instructions may be loaded into an algorithmic pattern generator, which may execute the instructions to perform a sequence of commands on the semiconductor device.

Each command provided to the semiconductor device may take a period of time to perform. For example, there may be a period of time defined by a specification of that device. In order to allow time for each command to be performed, the instructions may include instructions which cause the semiconductor device to perform no action for at least the necessary amount of time for the command issued as part of a previous instruction to be performed.

### BRIEF DESCRIPTION OF THE DRAWINGS

FIG. 1 is a cross-section of a system-in-package (SiP) device according to some embodiments of the present disclosure.

FIG. 2 is a block diagram of loading instructions into a memory according to some embodiments of the present disclosure.

FIG. 3 is a block diagram of instructions which may be loaded into an algorithmic pattern generator according to some embodiments of the present disclosure.

FIG. 4 is an algorithmic pattern generator according to some embodiments of the present disclosure.

FIG. 5 is a block diagram of a no-operation control circuit according to some embodiments of the present disclosure.

FIG. 6 is a counter circuit according to some embodiments of the present disclosure.

FIG. 7 is a schematic diagram of a command mixer according to some embodiments of the present disclosure.

FIG. 8 is a timing diagram of an example operation of an algorithmic pattern generator according to some embodiments of the present disclosure.

FIG. 9 is a block diagram of a multi-phase algorithmic pattern generator according to some embodiments of the present disclosure.

FIG. 10 is a block diagram of a phase controller circuit according to some embodiments of the present disclosure.

FIG. 11 is a block diagram of a counter circuit according to some embodiments of the present disclosure.

FIG. 12 is a block diagram of a counter circuit according to some embodiments of the present disclosure.

FIG. 13 is a block diagram of a command mixer according to some embodiments of the present disclosure.

FIG. 14 is a timing diagram of an example operation of a multi-phase algorithmic pattern generator according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Algorithmic pattern generators (APGs) may be useful for performing a sequence of operations on a semiconductor device. The APG includes one or more storage structures which are used to store instructions. Based on those instructions, when the APG is active, it may provide a sequence of commands which may cause various actions to be performed by the semiconductor device. An APG may be useful in scenarios where it is desirable to generate a relatively long sequence of operations from a relatively limited amount of instructions. For example, a test circuit, such as a built-in self-test (BIST) circuit may include an APG which is used to execute a test on a semiconductor memory device. For example, the BIST circuit may write a pattern of data to specified memory cells of a memory array of the memory, and then read the data stored in those memory cells. The read data may be compared to the written data, and a result of the test may be based, at least in part, on that comparison.

The timing it takes to perform various operations in the semiconductor device may be defined by a specification of the device. For example, a write operation on a memory may take a time tWTR, which may be a specified number of clock cycles of the memory. In order to manage the timing commands issued by the APG, the instructions loaded in the APG may generally include no-operation (NOP) commands. Since the APG circuit may generally issue commands with a set timing based on a clock signal, the instructions may tell the APG circuit to issue an appropriate number of NOP commands after each active command in the instructions. For example the instructions may include a write command followed by instructions to perform a NOP command tWTR times. The BIST circuit may have a limited area of storage in which to store the instructions. Accordingly, it may desirable to reduce the footprint (e.g., the number of bits, the number of lines of code) that the instructions take up.

The present disclosure is drawn to apparatuses, systems and methods for in-line no-operation repeat commands. The instructions loaded in an APG of the present disclosure may include a number of lines of instruction, each of which may include an active command (e.g., read, write, pre-charge, activate, etc.) and an NOP repeat command. The NOP repeat command may be a value which represents how many NOP operations should be performed after the active command is performed. Accordingly, since the NOP repeat command is a value stored in-line with the associated active command, it may require less storage space than an NOP command and a repeat instruction stored on a separate line of the instructions. This may reduce the number of bits which are required to be stored in the APG's instruction storage, which in turn may reduce the size required for the data storage and/or increase the speed at which the APG is able to operate the data storage.

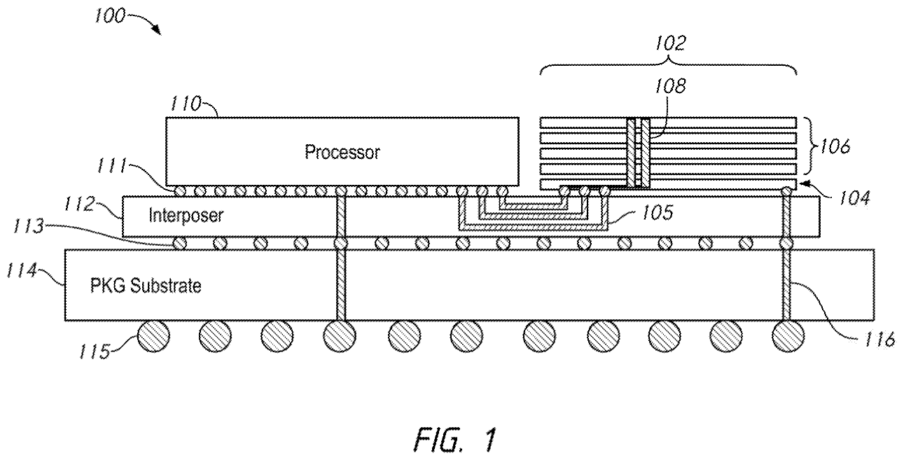

FIG. 1 is a cross-section of a system-in-package (SiP) device according to some embodiments of the present disclosure. The SiP device 100 includes a memory device 102 and a processor 110, which are packaged together on a package substrate 114 along with an interposer 112. The memory device 102 may include an APG circuit as part of a BIST circuit used to perform tests of the memory device 102.

The memory device 102 as shown in the example of FIG. 1 may be a high bandwidth memory (HBM) device, which includes an interface die (or logic die) 104 and one or more memory core dies 106 stacked on the interface die 104. The memory device 102 includes one or more through silicon vias (TSVs) 108, which are used to couple the interface die 104 and the core dies 106. The processor 110 may act as a host device of the SiP 100.

The processor 110 and the memory device 102 both are coupled to the interposer 112 by a number of micro-bumps 111. Channels 105 through the interposer 112 may couple some of the micro-bumps 111 which are coupled to the processor 110 to respective ones of the micro-bumps 111 which are coupled to the memory device 102 to form an interface between the memory device 102 and processor 110. The interposer 112 may be coupled to the package substrate by one or more bumps such as C4 bumps 113. The package substrate 114 includes bumps 115, some of which are coupled to the processor 110 and some of which are coupled to the memory device 102. Direct access (DA) bumps 116 are coupled through the package substrate 114 and interposer 112 to the interface die 104.

The direct access bumps 116 (e.g., the portion of the bumps 115 which are coupled to the interface die 104) may be organized into a probe pad. In some embodiments, an external device, such as a tester, may be coupled onto the probe pad in order to send and receive signals from the memory device 102, without those signals needing to pass to the processor 110. The tester may provide one or more lines of instructions to an APG of the memory device 102 (e.g., as part of BIST circuit included in the interface die 104). In some embodiments, a tester may be coupled to processor 110, which may pass the instructions to the BIST circuit. In some embodiments, the processor 110 may generate the instructions and load them into the memory device 102.

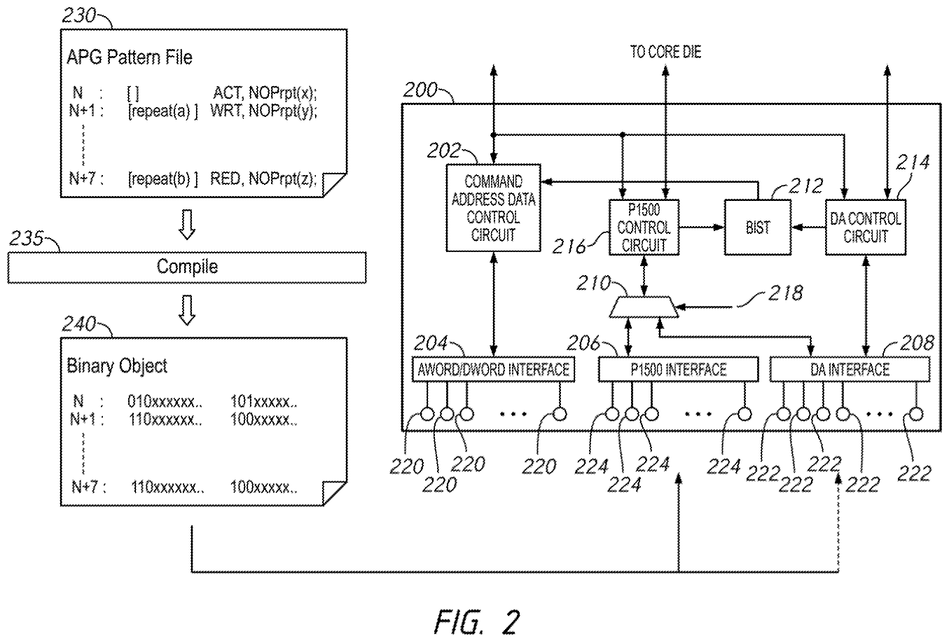

FIG. 2 is a block diagram of loading instructions into a memory according to some embodiments of the present disclosure. FIG. 2 includes an interface die 200, which may be included in the interface die 104 of FIG. 1 in some embodiments. For ease of explanation, only certain components of the interface die 200 which are directly relevant to the loading of the instructions of block 230 are shown. It should be understood that other components may be included in the interface die 200.

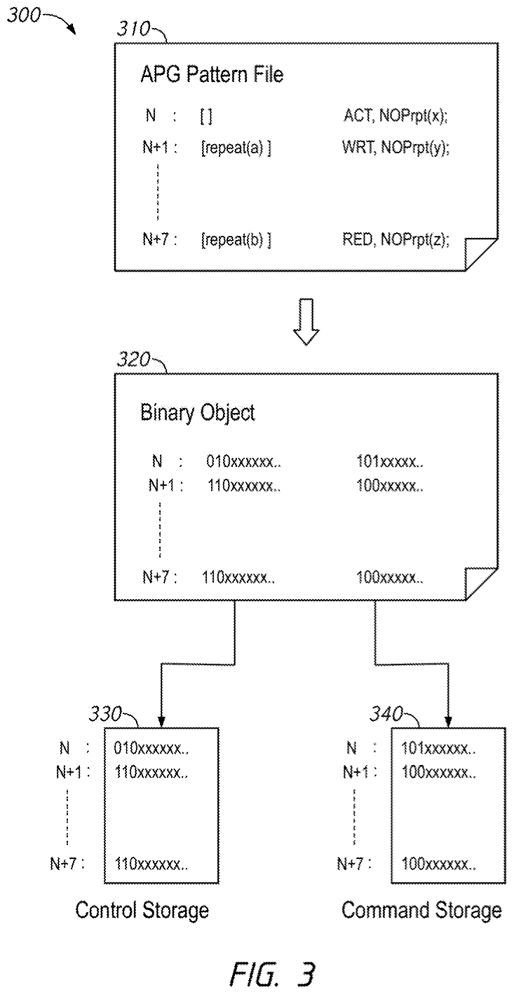

The interface die 200 is shown receiving instructions in block 230. The instructions of block 230 represent a set of example instructions which may be uploaded to a BIST circuit 212 of the interface die 200. In some embodiments, the instructions of block 230 may be loaded by an external device, such as a tester, which may be coupled to the memory device. In some embodiments, the instructions may be provided by a host device (e.g., processor 110 of FIG. 1). An example of the format and contents of the instructions is described in more detail in FIG. 3.

The instructions of block 230 may be input to a compiler 235, which may compile the instructions into a format readable by the APG (e.g., in the BIST circuit 212), as shown by the compiled instructions of block 240. For example, the compiler 235 may translate the instructions into a string of binary bits such as a machine code. The compiler 240 may be part of the interface die 200 or may be performed prior to the instructions 240 being provided to the interface die 200. In some example embodiments, the instructions may be compiled before the instructions are loaded into an external device such as a tester. In some embodiments, the instructions may be compiled by the tester.

The interface die 200 may receive information through a number of different sets of terminals. The terminals may represent bumps or physical connections which may be used to convey information to or from the interface die 200. The terminals may be arranged in sets which each communicate using one or more communication protocols. The sets of terminals are each coupled to an interface circuit associated with that set which is used to interpret information received on that set of terminals into a form usable by the interface die 200, and to translate information in the interface die 200 into signals which can provided through the terminals to components outside the interface die 200.

The interface die 200 may include a set of native terminals 220 coupled to a native interface circuit 204. The native terminals 220 may couple the interface die 200 to a host device (e.g., processor 110 of FIG. 1). The native terminals 220 may be coupled to the channels 105 in some embodiments. The native interface circuit 204 may translate between signals sent along the native terminals and data words (DWORDS) and address words (AWORDS) used by the interface die 200. In some embodiments, the native interface circuit 204 may control a timing at which AWORDs and DWORDs are received at the native terminals 220 and/or may serialize or deserialize the information received at the native terminals 220.

The AWORDS may include address information which indicates one or more memory cells in a core die, and command information which includes information about what operation is to be performed on those memory cells. The DWORD may include data, such as data to be written to the memory cells (indicated by the address information in the AWORD) or data read from memory cells. The native interface 204 may provide the AWORDS and DWORDS to a command/address control circuit 202, which may control the routing of various signals based on the information in the AWORD. The native interface 204 may also receive AWORDs and DWORDs from the command/address control circuit 202, and may provide the AWORDs and DWORDs to the native terminals 220 to be provided to an external device (e.g., processor 110 of FIG. 1).

As an example, each core die (e.g., core dies 106 of FIG. 1) may include a memory array, which includes a number of memory cells. The memory cells may be located at the intersection of word lines (rows) and bit lines (columns). Groups of memory cells may be organized together into banks. Accordingly, the address information in an AWORD may include a bank address which specifies one or more banks, a row address which specifies one or more rows, a column address which specifies one or more columns and combinations thereof. In some embodiments, there may be a core die address associated with a particular core die. In some embodiments, information may be provided in common to all of the core dies.

The interface die 200 may include a set of P1500 terminals 224 and a P1500 interface circuit 206. The P1500 terminals 224 may send and receive information between the interface die 200 and a host device (e.g., along channels 105 of FIG. 1). The P1500 terminals 224 may send and receive signals which are formatted based on a test signal protocol, such as the IEEE 1500 protocol. The P1500 terminals 224 may send and receive information which are used to perform tests on one or more of the core dice. In some embodiments, the information transmitted via the P1500 terminals 224 may be formatted differently than the AWORDS and DWORDs transmitted via the native terminals 220. For example, the P1500 terminals 224 may receive instructions, such as the compiled instructions of box 240, to be loaded into an APG of the BIST 212.

The interface die 200 may include direct access terminals 222. The direct access terminals 222 (or DA terminals) may be organized into a probe pad which may allow an external device to access the interface die 200 (e.g., direct access terminals 116 of FIG. 1). Signals may be received through the DA terminals through one or more different protocols. For example, in some embodiments, AWORDs and DWORDs similar to those along the native terminals 220 may be sent and received through the DA terminals 222. In some embodiments, signals in the P1500 protocol may be sent and received through the DA terminals 222. The DA interface circuit 208 may determine whether to couple the DA terminals 222 to the P1500 control circuit 216 or to a DA control circuit 214. For example, one of the DA terminals 222 may be used as a DA enable terminal, and when a signal applied to the DA enable terminal is active, multiplexer 210 may provide signals from the DA interface 208 to the P1500 control circuit 216.

The interface die 200 may include a built-in self-test (BIST) circuit 212 which may be used to perform one or more tests on one or more of the core die. The BIST circuit 212 may include an algorithmic pattern generator (APG) which is used to provide a sequence of commands for performing the test, based on executing instructions (e.g., the instructions of block 230 and/or 240) loaded in the APG. The instructions (e.g., in the form of the machine code of block 240) may be loaded into the BIST circuit 212 through one or more of the sets of terminals 220-224. For example, the machine code may be loaded through the P1500 terminals 224, may be loaded through the DA terminals 222 in a P1500 format, and/or may be loaded through the DA terminals 222 in another format.

The BIST circuit 212 may perform a test by providing commands, addresses, and data, for example in the form of AWORDs and DWORDs, to the command address control circuit 202, which may then access the core dies as normal. In general, a test operation performed by the BIST circuit 212 may include executing a line of instruction to generate and provide a DWORD including test data along with an AWORD which includes commands to write the test data to one or more specified memory cells in one or more core dice based on the address information in the AWORD. At a later time, the BIST circuit 212 may execute a line of instruction to generate and provide an AWORD which includes commands to read the information stored in the memory cells. The data read from the memory cells may then be compared to the original test data written to those memory cells. In some embodiments, the BIST circuit 212 may perform the comparison and may generate result information which may later be provided out of the interface die (e.g., through the DA terminals 222 and/or P1500 terminals 224). In some embodiments, the read data may be provided out of the interface die 200 for comparison by a different component such as a tester or a host device.

When activated, the APG in the BIST circuit 212 may provide a series of commands, (along with any associated addresses and/or data) based on the instructions (e.g., 230/240) loaded in the APG. In order to manage the timing of various operations, the BIST circuit 212 may operate in synchronization with a clock signal of the interface die 200 (e.g., a clock signal of the memory device). For example, when active, the BIST circuit 212 may provide one or more commands with each cycle of the clock signal. Accordingly, to control the timing of a test operation, the instructions loaded in the BIST circuit 212 may include instructions on how to generate a sequence of command such that there is a command for each time slot (e.g., each clock cycle) in which the BIST circuit 212 is expected to issue a command.

FIG. 3 is a block diagram of instructions which may be loaded into an algorithmic pattern generator according to some embodiments of the present disclosure. The instructions of block 310 and the instructions of block 320 may, in some embodiments, be included in the instructions of blocks 230 and 240 of FIG. 2, respectively. For the sake of brevity, only a portion of the instructions dealing with the commands provided as part of a test are shown. It should be understood that the instructions may include additional fields which may be used, for example, to control the data of the test pattern and/or the address(es) which tests are performed on.

As shown in block 310, the instructions include a number of lines, each of which includes a number of commands and instructions. The first column of block 310 represents a line number (from N to N+7) which is used to index the lines of code. In some embodiments, the line number may generally represent an order in which the instructions are executed by the APG. For example, instructions of line N may be executed before line N+1 is executed and so forth. In some embodiments, one or more of the instructions in a given line may cause the APG to change the behavior in which it executes the lines of instruction.

The second column shows a control instruction portion of the instructions. The third column shows a command instruction portion of the instructions. The control instruction portion may include information about how to execute the command instruction portion. In some embodiments, the control portion of the instructions may include instructions (e.g., conditionals such as ‘if’ statements, repeat instructions) which may cause the lines to operate in a different order than strictly numerical. For example, a control portion may instruct that a previous line should be returned to, or that a subsequent line should be skipped to after the current line is performed. The control portion may also instruct that a given line should be repeated a number of times before a next line is executed.

The third column shows a command instruction portion of each line which includes an active command and an NOP repeat command (NOPrpt). The active command may be a command which is provided to the core die (e.g., through the command address control circuit 202 of FIG. 2) in order to cause an operation to be performed on the memory cells specified by accompanying address information. An example active commands may include an activate command (ACT) which causes the specified row(s) of memory to be a ‘opened’ so that the data of the memory cells along that row can be accessed. An example active command may include a read command (RED) which causes data to be read out from the memory cells of an ‘opened’ row and a write command (WRT) which causes data (e.g., in an accompanying DWORD) to be written to the memory cells of an opened row. An example active command may also include a pre-charge command (PRE), which ‘closes’ the row(s) specified by accompanying address information.

Along with the active command, the command instruction portion of each line may also include a NOP repeat command. The NOP repeat command may indicate a number of times that a no-operation command should be performed after the active command is performed. The NOP repeat command may be represented by a value (e.g., X) which is the number of times that a NOP command should be performed. In some embodiments, after being compiled the instructions may only store the value X (e.g., as a binary number) in a field of each line of storage reserved for the NOP repeat command. In some embodiments, the instructions may cause an NOP command to be provided X times. In some embodiments, the instructions may cause an NOP command to be provided for X clock cycles. In some embodiments where the APG provides a command multiple times per clock cycle, such as on each phase of the clock cycle, the NOP command may be provided each time a command is provided until X total NOP commands are issued. Once the active command and X NOP commands are provided (e.g., to a command bus), then a next line of instructions (which may be determined based on the control instruction portion) may be executed.

The control instruction portion may include various control instructions which modify how the command instruction portion is executed. For example, the control instruction portion may include a repeat command (e.g., repeat(a)) which may cause the command instruction portion to be repeated a number of times before the next line is executed.

Block 320 shows that both the control and command instruction portions are compiled into a binary code. The different portions of the compiled code may be stored in separate portions of the APG. For example, a control storage 330 may be used to store the compiled control instruction portion and a command storage 340 may be used to store the compiled command instruction portion. It should be understood that instructions may generally be compiled before they are loaded into the APG. However, for clarity, non-compiled instructions will generally be described throughout to describe the instructions loaded in the APGs.

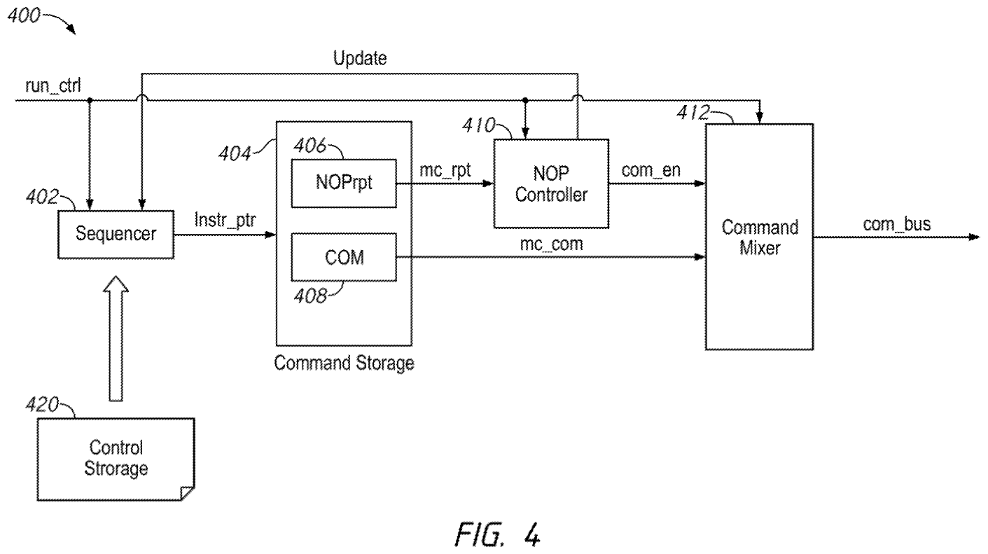

FIG. 4 is an algorithmic pattern generator according to some embodiments of the present disclosure. The algorithmic pattern generator (APG) 400 may, in some embodiments, be included in the BIST circuit 212 of FIG. 2. The APG 400 may execute instructions (e.g., the instructions of boxes 230/240 of FIG. 2 and/or boxes 310/320 of FIG. 3) to provide a series of commands as the output signal Com_bus to a command bus. The APG 400 provides the commands with a timing based on a clock signal (not shown). The APG 400 may provide a command (such as an NOP command or an active command 408) responsive to each time the clock signal is received (e.g., each rising edge of the clock signal, each falling edge of the clock signal, etc.). In some embodiments, the APG 400 may receive and respond to multiple phases of a clock signal (e.g., both rising and falling edges) and may thus provide a command as the output signal com_bus multiple times per clock cycle.

The APG 400 includes a control storage 420 and command storage 404. The control storage 420 may, in some embodiments, be included in the control storage 330 of FIG. 3. The control storage 420 may be used to a store a control instruction portion of the lines of instruction loaded in the APG 400. The control storage 420 may be a data storage structure capable of storing a number of bits of information, such as the machine code shown in block 330 of FIG. 3. In some embodiments, the control storage 420 may be a RAM.

The command storage 404 may be used to store a command instruction portion of the lines of instruction loaded in the APG 400. The command storage 404 may, in some embodiments, be included in the command storage 340 of FIG. 3. The command instruction portion of a given line of instructions includes an NOP repeat command, such as a NOP repeat value 406 and an active command COM 408. The command storage 404 may, in some embodiments, be data storage structure similar to the control storage 420.

The instructions in the control storage 420 may operate a sequencer 402. The sequencer 402 may provide an instruction pointer Instr_ptr which may determine which line of the instructions (e.g., which of the stored command instruction portions) in the command storage 404 is being executed. The sequencer 402 may also receive a control signal run_ctrl and an update signal. The signal run_ctrl may be an enable signal, which is at an active level to indicate when the APG 400 should execute the lines of instruction. When the enable signal run_ctrl is at an inactive level, it may inactivate the APG 400. The APG 400 may also receive a clock signal (not shown), such as a clock the system (e.g., the SiP 100 of FIG. 1) including the APG 400.

An activation of the update signal update may be used to indicate that a current line of commands in the command storage 404 has finished execution. Responsive to an activation of the signal update, the sequencer 402 may update the pointer Instr_ptr. The sequencer 402 may update the pointer Instr_ptr based on the control instruction portion in the control storage 420. In some embodiments, the sequencer 402 may determine whether or not, and where, to move the pointer Instr_ptr based on the control instruction portion stored in the control storage 420 associated with the line of instructions which is being executed. For example, if there are no control instructions associated with the current line, then responsive to an activation of the signal update the sequencer 402 may move the instruction pointer Instr_ptr to a next line of instructions. If the control instructions instruct a certain number of repeats, then the sequencer 402 may determine if the current line has been performed that many times. If so, then the sequencer 402 may move the pointer Instr_ptr to a next line, and if not the pointer Instr_ptr may stay on the same line. Other control instructions may lead to other behaviors of the sequencer 402.

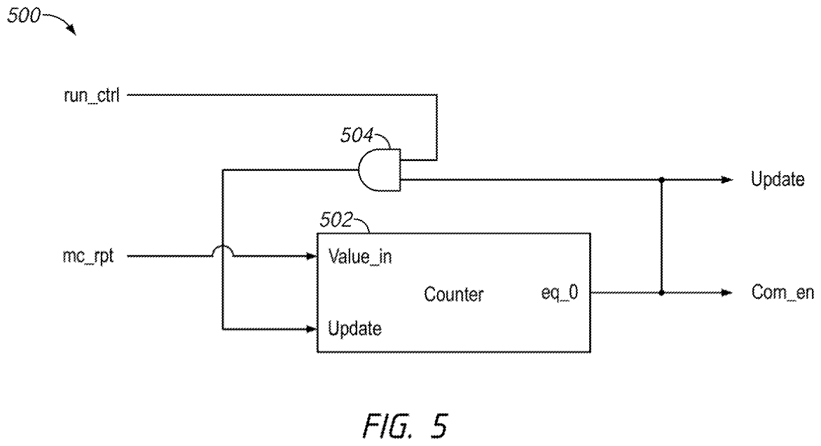

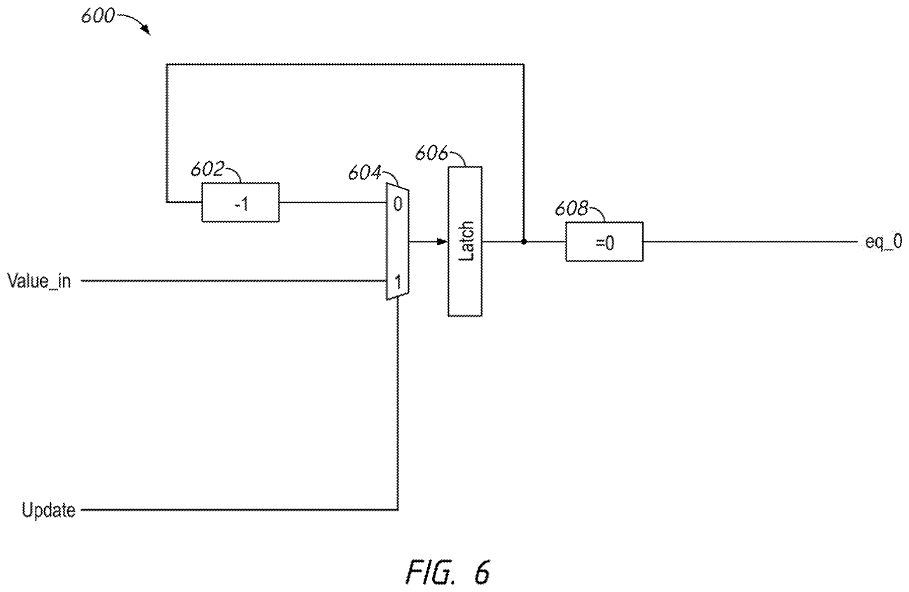

The command storage 404 may provide a repeat value mc_rpt based on the value of the NOP repeat command 406 of the line indicated by the pointer Instr_ptr, and may provide a command mc_com based on the active command COM of the same line. The value mc_rpt may be provided to an NOP controller circuit 410, which may provide a command enable signal com_en which indicates whether to provide the active command mc_com or an NOP command is provided as the signal Com_bus along the command bus. The NOP controller circuit 410 may also receive the enable signal run_ctrl which may activate the NOP controller circuit 410. The NOP controller circuit 410 may use a clock signal (not shown) to manage a timing, and may provide the signal update when the NOP repeats for a given line of instructions (e.g., as indicated by the value mc_rpt) have been completed. For example, the NOP controller circuit 410 may count a number of times the clock signal is received (e.g., rising edges and/or falling edges) and then may provide the signal com_en and update at an active level after mc_rpt times the clock signal is received. An example NOP controller is described in more detail in FIGS. 5-6.

The APG 400 may include a command mixer circuit 412 which provides the signal Com_bus with a timing based on the clock signal (not shown) while the enable signal run_ctrl is at an active level. The contents of the output signal Com_bus are based on the states of the signals mc_com and com_en. For example, when the signal com_en is at a low logical level, then each time the clock signal is received, a NOP command may be issued as the signal Com_bus. When the signal com_en is at a high logical level, then when the clock signal is received the active command mc_com may be provided as the signal Com_bus. Accordingly, the NOP controller circuit 410 may control the number of times an NOP command is issued between each active command by providing the signals update and com_en based on the timing signal run_ctrl and the value mc_rpt.

FIG. 5 is a block diagram of a no-operation control circuit according to some embodiments of the present disclosure. The NOP control circuit 500 may, in some embodiments, be included in the NOP control circuit 410 of FIG. 4. The NOP control circuit 500 includes a counter circuit 502 and a logic gate 504. The NOP control circuit 500 receives a value mc_rpt, which is a value of a NOP repeat command (e.g., 406 of FIG. 4) at a value_in input terminal of the counter circuit 502. The value mc_rpt indicates a number of times that an NOP operation should be performed after a given active command. The value mc_rpt may be stored as a stored value in the counter circuit 502 when a high logical level is received at the update terminal of the counter circuit 502. Responsive to receiving the clock signal (e.g., receiving one or more phases of the clock signal), the counter circuit 502 may change the stored count value and compare it to a threshold. When the stored value reaches the threshold, the counter circuit 502 may provide the signal com_en from an output terminal eq_0. The signal com_en may also act as the update signal update. For example, the counter circuit 502 may decrement the stored count value responsive to each received clock signal, and may provide the signal com_en at an active level when the stored count value reaches 0.

The update signal is provided to a terminal of a logic gate 504, which may be an AND logic gate. The other input terminal of the AND gate 504 is coupled the enable run_ctrl. Accordingly, when the signal update is at a high logical level and the enable signal run_ctrl is at a high logical level, the ANG gate 504 may pass a high logical level to the update terminal of the counter circuit 502. A high logical level at the update terminal may cause the counter circuit 502 to receive a new value of mc_rpt and store the value mc_rpt as the new stored count value.

FIG. 6 is a counter circuit according to some embodiments of the present disclosure. The counter circuit 600 may, in some embodiments, be included in the counter circuit 502 of FIG. 5. The counter circuit 600 includes a latch 606 which stores a stored count value. Each time a timing signal (not shown) is received by the counter circuit 600, it may cause the latch 606 to provide the current stored count value at an output terminal of the latch and store a new count value received at an input terminal of the latch.

The counter circuit 600 shows an embodiment where responsive to each time a clock signal is received, the stored count value in the latch circuit 606 is decremented, unless the signal update is active (e.g., at a high logical level) in which case a new value on the value_in terminal is stored in the latch 606. The counter circuit 600 includes a multiplexer 604 which determines whether a new value on a value_in terminal (e.g., mc_rpt) is stored in the latch 606 or whether the count value in the latch 606 continues to decrement. As shown in the example counter circuit 600, the multiplexer 604 has a first input terminal coupled to the output of a subtractor circuit 602, and a second input terminal coupled to the terminal value_in. The selector terminal of the multiplexer 604 is coupled to the signal update.

Accordingly, when the signal update is high, the value on the value_in terminal may be provided to the input terminal of the latch 606 and stored as the new stored count value. When the signal update is at a low level, the current value of the stored count value is provided to the subtractor circuit 602, which decrements the current count value, and provides the decremented value through the multiplexer 604 to be stored in the latch 606 as the new stored count value.

Each time the stored count value is provided by the latch 606, a comparator circuit 608 may check to see if the stored count value is 0 or not. If the stored count value is not equal to 0, then the comparator circuit 608 may provide a signal (e.g., com_en) to the terminal eq_0 at a low level. The stored count value is equal to 0, the provided value may be at a high logical level.

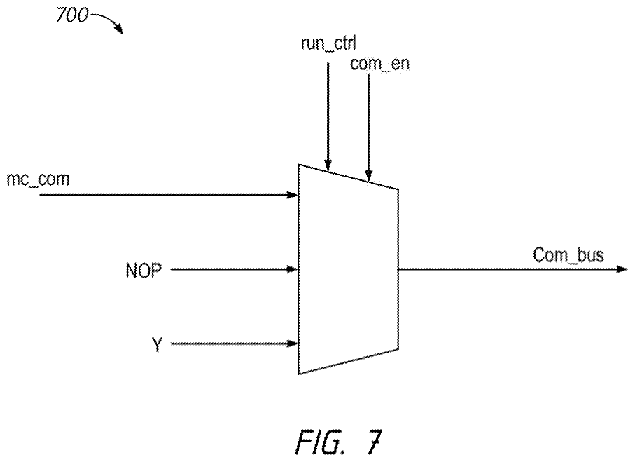

FIG. 7 is a schematic diagram of a command mixer according to some embodiments of the present disclosure. The command mixer 700 may, in some embodiments, be included in the command mixer 412 of FIG. 4. The command mixer 700 may act as a multiplexer to provide commands as the signal Com_bus to a command bus. The example command mixer 702 includes three input terminals for commands which are coupled to mc_com, and NOP command, and an additional input Y. Which of those commands is provided as the signal com_bus is based on the states of the enable signal run_ctrl and the signal com_en from the NOP control circuit (e.g., 410 of FIG. 4). Table 1 shows an example logic table for the operation of the command mixer 700.

TABLE 1
Example operation of Command Mixer

| run_ctrl | com_en | com_bus |
|---|---|---|
| 0 | x | Y |
| 1 | 0 | NOP |
| 1 | 1 | mc_com |

In Table 1, the first two columns represent one of the control signals which control the output of the command mixer 700. The third column represents the state of the signal com_bus based on the states of the first two columns. A value of 1 indicates that the signal is at a logical high, while a 0 represents a logical low. An x indicates that the value of that signal does not matter. Accordingly, when the timing signal run_ctrl is low, regardless of the state of com_en, the output signal com_bus is the additional input Y. When run_ctrl is high but com_en is low, the output value com_bus is an NOP command. When run_ctrl is high and com_en is high, the output value com_bus is the active command mc_com.

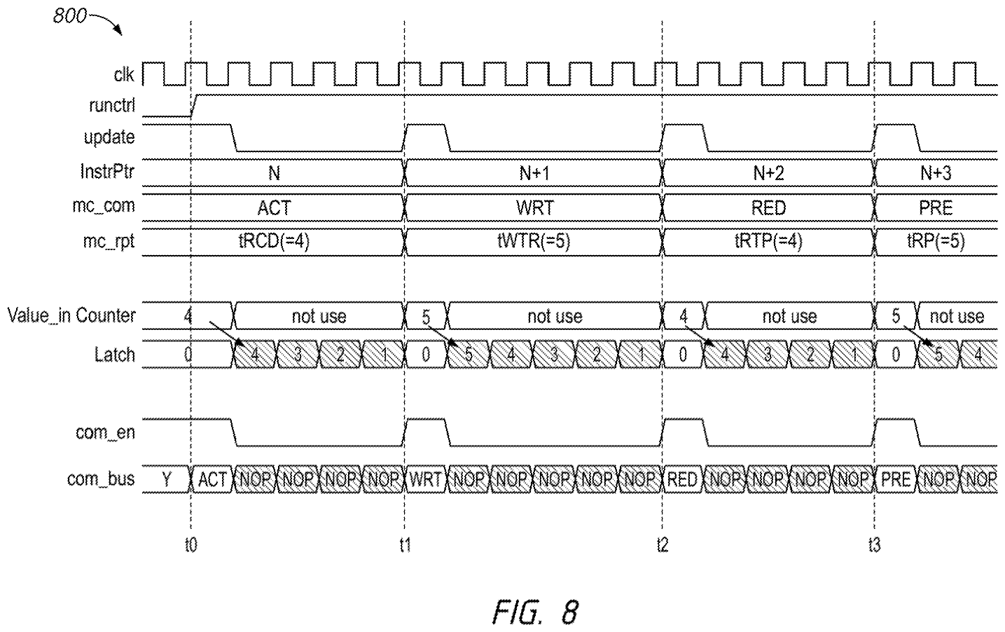

FIG. 8 is a timing diagram of an example operation of an algorithmic pattern generator according to some embodiments of the present disclosure. The timing diagram 800 may represent the operation of an APG such as the APG 400 of FIG. 4 in some embodiments.

The first line of the timing diagram 800 shows a clock signal clk, which may control timing of the various operations. The second line shows an enable signal run_ctrl which is used to enable the APG. The next line shows the update signal update, provided by an NOP controller (e.g., 410 of FIG. 4). The next line shows the instruction pointer Instr_ptr which may be provided by a sequencer (e.g., 402 of FIG. 4) to indicate which line of instructions being executed. The fifth line shows the active command mc_com on the executed line of instructions, the sixth line shows the value of the NOP repeat command associated with the executed line. The seventh line shows the value on the input terminal Value_in of the counter circuit (e.g., 502 of FIG. 5 and/or 600 of FIG. 6). The eighth line shows the stored value in a latch circuit of the counter (e.g., 606 of FIG. 6). The ninth line shows the command enable signal com_en provided by the NOP controller (e.g., 410 of FIG. 4) and the tenth line shows the state of the signal com_bus provided to the command bus by the command mixer (e.g., 412 of FIG. 4).

Table 2, below, shows an example of a set of instructions which may have been loaded into the APG which generate the waveforms of the timing diagram 800. For brevity, the example instructions of Table 2 do not include any control instructions. However, it should be understood that various control instructions may also be used together with the NOPrpt commands in some embodiments. For example, if line N of Table 2 below included the control instruction repeat(a), then the sequence of commands ACT+NOP tRCD times would be repeated ‘a’ times before the line N+1 is executed.

The set of active commands in the example instructions of Table 2 include an activate command ACT, a write command WRT, a read command RED, and a pre-charge command PRE. Each of those commands has an associated amount of time tRCD, tWTR, tRTP, and tRP. Accordingly, the APG may provide an ACT command, then a NOP command tRCD times, then a WRT command, then tWTR NOP commands, etc.

TABLE 2
Example Instructions Loaded into an APG

| Line Number | Control Instruction | Command Instruction | Expected Output |
|---|---|---|---|
| N | [ ] | ACT, NOPrpt(tRCD) | ACT, NOP, NOP . . . |
| | | | (ACT + NOP tRCD times) |
| N + 1 | [ ] | WRT, NOPrpt(tWTR) | WRT, NOP, NOP . . . |
| | | | (WRT + NOP tWTR times) |
| N + 2 | [ ] | RED, NOPrpt(tRTP) | RED, NOP, NOP . . . |
| | | | (WRT + NOP tRTP times) |
| N + 3 | [ ] | PRE, NOPrpt(tRP) | PRE, NOP, NOP . . . |
| | | | (PRE + NOP tRP times) |

At an initial time t0, the signal run_ctrl rises to a high level which enables the APG. The instruction pointer instr_ptr refers to a first line N, which includes the command ACT and NOPrpt(tRCD). For the sake of explanation, in this example, the value of tRCD is four clock cycles. Accordingly, at t0 the value of Value_in is also four. The latch may initialize to stored value of zero. The signal com_en may initially start a high logical level, and accordingly the command ACT may be provided as the output signal com_bus. Since the signal com_en is at a high level, the signal update may also be at a high level, which may cause the value tRCD (e.g., 4) to be stored as the stored value Latch in a counter of the NOP controller circuit on a next clock cycle (e.g., a next rising edge of clk). Accordingly, since a non-zero value is the stored count value, the signal com_en and update may fall to a low logical level. Since com_en is at a low level, the command NOP may be provided as the signal on com_bus. With each rising edge of the clock clk while update is at a low logical level, an NOP may be issued as the signal com_bus and the count value may decrement.

At a first time t1, the stored count value may reach 0 (e.g., after four NOP's have been issued). This may cause the NOP controller circuit to provide the signals com_en and update at a high logical level. The signal update being at a high logical level may cause the sequencer to update the pointer instr_ptr to a next value, which in this case is N+1. The sequencer may determine the next value of the pointer based on the control instruction of line N, which in this example is blank (e.g., null value [ ]). The line N+1 has a different value of the active command, and so mc_com may change to WRT. The line N+1 also has a different NOP repeat value, tWTR, which in this example is five, and so the Value_in changes to five. On a next clock cycle, the value tWTR (e.g., five) is loaded as the stored count value Latch and accordingly NOPs are provided on the next five clock cycles as the value Latch decrements.

In a similar fashion, at a time t2, the signals com_en and update may rise to a high level again, the instruction pointer instr_ptr moves the N+2, the active command value mc_com changes to RED and so the command RED is provided and then tRTP (e.g., 4) NOPs are issued as the output command com_bus. The timing chart continues at a time t3 when the command pointer moves to the next line and a pre-charge command PRE is issued as com_bus.

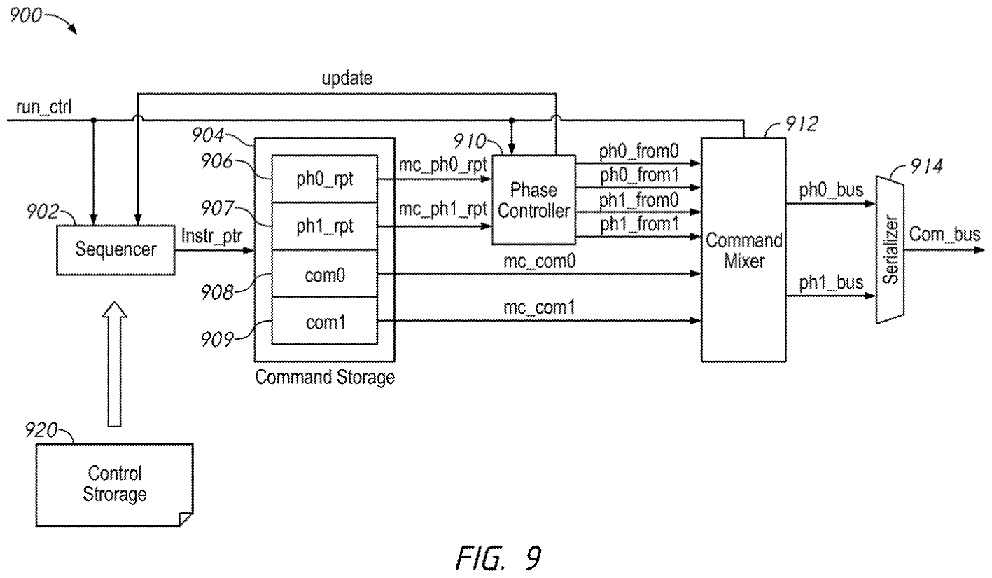

FIG. 9 is a block diagram of a multi-phase algorithmic pattern generator according to some embodiments of the present disclosure. The APG 900 may, in some embodiments, be included in the BIST circuit 212 of FIG. 2. The APG 900 may generally be similar to the APG 400 of FIG. 4. For the sake of brevity, features and operations similar to those in the APG 400 of FIG. 4 will not be repeated again in regards to FIG. 9.

The APG 900 may operate in a multi-phase manner, and may update the signal com_bus provided to the command bus multiple times for each cycle of the clock signal. In particular, the APG 900 may update the signal com_bus responsive to both a rising edge of the clock signal and the falling edge of the clock signal. This may allow for a faster operation of the APG 900 compared to the APG 400.

In the embodiment of the APG 900, each line of instructions includes a command instruction portion which includes a first active command, a first NOP repeat command associated with the first active command, a second active command, and a second NOP repeat command associated with the second active command. The command storage 904 for a line of the instructions may include a first phase NOP repeat 906 (ph0_rpt) and second phase NOP repeat 907 (ph1_rpt) which may provide the value mc_ph0_rpt for the first NOP repeat command the value mc_ph1_rpt for the second NOP repeat command respectively. The command storage 904 includes a first active command 908 com0 which provides the value mc_com0 and a second active command 909 com1 which provides the value mc_com1.

The phase controller circuit 910 may operate in a manner analogous to the NOP controller circuit 410 of FIG. 4. The phase controller circuit 910 receives the signals mc_ph0_rpt and mc_ph1_rpt from the command storage 904 along with the enable signal run_ctrl. The phase controller circuit 910 provides control signals ph0_from0, ph0_from1, ph1_from0, and pho1_from1 to the command mixer 912. The command mixer 912 provides a signal ph0_bus and pho1_bus. The phase controller 910 may determine if the first phase (e.g., the rising edge) and the second phase (e.g., the falling edge) of a given clock cycle are each going to be NOP commands, from the first active command 908 or the second active command 909 and may determine the states of the set of control signals accordingly. The phase controller 910 may include counter circuits which may determine how many phases of the clock signal are allocated to the first active command first set of NOP commands and the second active command and second set of NOP commands.

The command mixer 912 may receive the control signals ph0_from0, ph0_from1, ph1_from0, and ph1_from1 from the phase controller 910, as well as the active commands mc_com0 and mc_com1. Based on the states of these signals (and the enable signal run_ctrl), the command mixer 912 provides a first phase bus signal ph0_bus and a second phase bus signal ph0_bus. When the enable signal run_ctrl is active, the two phase bus signals may each be either an NOP command or one of the two active commands based on the states of the control signals from the phase controller circuit 910.

The APG 900 includes a serializer circuit 914 which provides the signal ph0_bus or the signal ph1_bus as the output signal com_bus. The serializer circuit 914 may, in some embodiments, alternate between providing ph0_bus and ph1_bus as the output signal com_bus. The serializer may provide the signals ph0_bus and ph1_bus responsive to different phases of a clock signal. For example, the signal ph0_bus may be provided as the signal com_bus responsive to a first phase of the clock signal (e.g., a rising edge of the clock signal) while the signal ph1_bus may be provided as the signal com_bus responsive to a second phase of the clock signal (e.g., a falling edge of the clock signal). Accordingly, two different signals may be provided as the output signal com_bus in every clock cycle (even if the two signals are the same value). Accordingly, the phase controller 910 and the command mixer 912 may update each full cycle of the clock signal, while the serializer 914 may use multiple inputs to update the output signal com_bus at each phase of the clock signal.

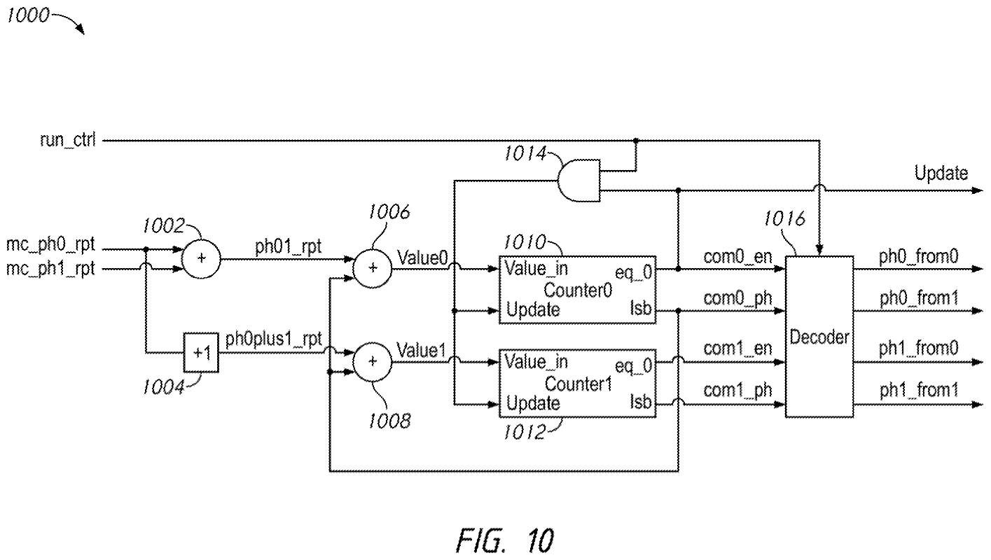

FIG. 10 is a block diagram of a phase controller circuit according to some embodiments of the present disclosure. The phase controller 1000 may, in some embodiments be included in the phase controller 910 of FIG. 9. The phase controller 1000 receives an enable signal run_ctrl and first and second NOP repeat values mc_ph0_rpt and mc_ph1_rpt respectively. The phase controller 1000 may also receive a clock signal (not shown) and may update at a rate based on the clock signal (e.g., responsive to each rising or falling edge of the clock signal).

The phase controller 1000 may work in a manner analogous to the operation of the NOP controller circuit 410 of FIG. 4. However, unlike using a single counter to track a number of times to determine when to provide an update signal and an enable signal com_en, the phase controller 1000 uses a pair of counter circuits 1010 and 1012 and a decoder 1016 to provide an update signal and four control signals, ph0_from0, ph0_from1, ph1_from0, and ph1_from1 to manage which of the first and second active command (e.g., 908 and 909 of FIG. 9) or an NOP command to provide.

The phase controller 1000 includes an adder circuit 1002 which receives the signals mc_ph0_rpt and mc_ph1_rpt and provides a signal ph01_rpt which is a sum of both of the repeat values. The value ph01_rpt is provided to a second adder circuit 1006, which sums the value pho01_rpt with signal com0_ph provided by the first counter circuit 1010. The signal com0_ph is provided from a least significant bit (lsb) terminal of the first counter circuit 1010. The signal com0_ph indicates if the first active command is performed on a first phase of a clock signal (e.g., a rising edge) or a second phase of a clock signal (e.g. a falling edge). The value value0 is updated by state of the signal com0_ph to account for the phase on which the commands are performed. The second adder circuit 1006 provides a value value0 to the input terminal value_in of the first counter 1010. The first counter circuit 1010 updates the stored count value to the value value0 responsive to the update signal update being at a high logical level.

The first repeat value mc_ph0_rpt is also provided to an increment circuit 1004, which increases the value mc_ph0_rpt by 1 to provide the value ph0plus1_rpt. The value ph0plus1_rpt is provided to a third adder circuit, which sums the values ph0plus1_rpt and com0_ph to provide a value value1, which is provided to an input terminal value_in of the second counter circuit 1012. The value value1 takes into account the number of clock phases between providing the first active command and the second active command. It increases the first NOP repeat value by one to account for the phase on which the active command occurs, and also includes phase information (e.g., in the form of adding com0_ph).

The first counter 1010 may count a number of phases of a clock signal (e.g., a number of rising edges and falling edges of the clock signal) between issuing the first active command at a first time, and issuing a next first active command. In other words, the first counter circuit 1010 may count a number of operations on a currently executed line of the instructions. This may be based, at least in part, on the number of NOP repeats which follow the first active command and the second active command (e.g., the sum ph01_rpt). The first counter 1010 may provide a signal com0_en which is at a high logical level to indicate that the first active command should be provided as the output signal com_bus. The first counter 1010 also provides a signal com0_ph which, when com0_en is at a high level, indicates if the first active command should be issued responsive to a first phase of the clock signal or a second phase of the clock signal. For example, when the signal com0_ph is at a low logic level it may be associated with a rising edge of the clock signal, and com0_ph at a high logic level may be associated with a falling edge of the clock signal.

The second counter 1012 may work in a manner analogous to the first counter 1010, except the second counter 1012 counts the number of clock phases from issuing a first active command until it is time to issue the second active command. This may be based, in part on the number of NOP commands which follow the first active command (e.g., the value of the first NOP repeat command, mc_ph0_rpt). The number of clock phases may be incremented by one (e.g., by incrementer 1004) to account for the first active command also taking up a clock phase. As with the value provided to the first counter 1010, value0, the second value value1 may also be adjusted b the value com0_ph to account for a phase offset in the signal.

The counters 1010 and 1012 have update terminals which are coupled to an output of an AND gate 1014. The AND gate provides a high logical level to the update terminals when the signal update is at a high logical level and the enable signal run_ctrl is at a high logical level. The signal update is at an active level based on the level of the signal com0_en provided by the first counter circuit 1010. The signal com0_en may indicate that it is time to provide the first active command (e.g., 908 of FIG. 9) again. Accordingly, the signal com0_en may be used as the update signal to indicate that it is time for the sequencer (e.g., 902 of FIG. 9) to update the value of the instruction pointer to a next line of instructions. The update signal is coupled to one of the input terminals of an AND gate 1014 which has a second input terminal coupled to the enable signal run_ctrl.

When the value on the update terminals is at a low logical level, responsive to each cycle of the clock signal (e.g., each rising or falling edge), the counters 1010 and 1012 may decrement a stored value and provide an output value com0_en and com1_en respectively based on the state of the stored value. The first counter 1010 may provide the signal com0_en based on the stored value before it is updated (e.g., decremented) responsive to the clock signal. In other words, the output com0_en may be based on a previous state of the stored value. The second counter 1012 may provide the signal com1_en based on the stored value after it is updated responsive to the clock signal. In other words, the output com1_en may be based on a current state of the stored value.

The decoder circuit 1016 may receive the signals com0_en, com0_ph, com1_en, com1_ph, and the enable signal run_ctrl, and may provide the phase signals ph0_from0, ph0_from1, ph1_from0, and ph1_from1 based on those signals. The phase signals may in turn, be used by a command mixer (e.g., 912 of FIG. 9) to determine the state of the first and second phase bus signal ph0_bus and ph1_bus respectively. The decoder circuit 1016 may have a first counter portion which receives the signals com0_en and com0_ph and provides the signals ph0_from0 and ph1_from0 based on those signals. An example logic table for the operation of the first counter portion is given in Table 3, below. Similarly, a second counter portion of the decoder 1016 receives the signals com1_en and com1_ph and provides the signals ph1_from0 and ph1_from1 based on those signals. An example logic table for the operation of the second portion is given in Table 4, below.

TABLE 3
Logic Table for First Counter Portion of Decoder

| run_ctrl | com0_n | com0_ph | ph0_from0 | ph1_from0 |
|---|---|---|---|---|
| 0 | x | x | 0 | 0 |
| 1 | 0 | x | 0 | 0 |
| 1 | 1 | 0 | 1 | 0 |
| 1 | 1 | 1 | 0 | 1 |

TABLE 4
Logic Table for Second Counter Portion of Decoder

| run_ctrl | com1_en | com1_ph | ph0_from1 | ph1_from1 |
|---|---|---|---|---|
| 0 | x | x | 0 | 0 |
| 1 | 0 | x | 0 | 0 |
| 1 | 1 | 0 | 1 | 0 |
| 1 | 1 | 1 | 0 | 1 |

The signals ph0_from0 and ph0_from1 may be used to determine what signal is provided as the first phase bus signal phase ph0_bus. The signals ph0_from0 and ph0_from1 may determine if on a first phase (e.g., a rising edge of the clock signal) the first active command, the second active command, or an NOP command is provided as the signal ph0_bus. In a similar fashion, the signals ph1_from0 and ph1_from1 may be used to determine whether the first active command, the second active command, or an NOP command is provided as the signal ph1_bus which in turn is provided responsive to a second phase (e.g., a falling edge of the clock signal).

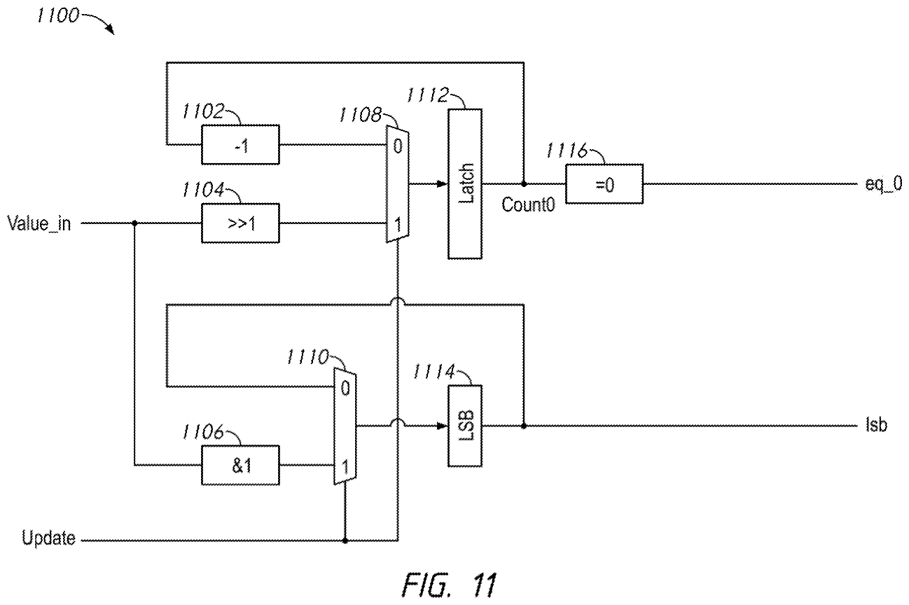

FIG. 11 is a block diagram of a counter circuit according to some embodiments of the present disclosure. The counter circuit 1100 may, in some embodiments, be included in the first counter circuit 1010 of FIG. 10. The counter circuit 1100 may receive a signal value0 at an input terminal value_in and provide a signal at an output terminal eq_0 which is the signal com0_en, and a signal at an output terminal lsb which is the signal com0_ph.

Similar to the counter circuit 600 of FIG. 6, the counter circuit 1100 has a latch 1112 which stores a stored count value count0. On each cycle of a received clock signal (e.g., each rising or falling edge) the stored count value count0 may be provided from an output terminal of the latch circuit 1112 to a decrementer circuit 1102, which reduces the value by one. The decremented value is provided to an input terminal of the latch circuit 1112 through multiplexer 1108 (as long as the update signal is inactive). Accordingly, on each cycle of the received clock signal, the stored count value count0 in the latch circuit 1112 is decremented. Responsive to each cycle of the received clock signal, the stored value count0 is also compared to 0 by the comparator 1116. The stored count value count0 is checked by the comparator 1116 before the latch 1112 stores the decremented count value. If the stored count value is 0, then the signal on the output terminal eq_0 is provided at a high level.

The counter circuit 1100 also includes a bit shifter circuit 1104 which removes phase information from the input value value_in. The first counter 1100 may receive an input value (e.g., Value0) which includes information about the first and second NOP repeat values and the phase. Since the phase information is a single bit added to the sum of the two NOP repeat values, the phase information may be located in a least significant bit of the input value. The bit shifter 1104 may remove the least significant bit from the input value. For example if the input of the bit shifter is the binary number nine (e.g., 1001) then the bit shifter 1104 may provide an output value of four (e.g., 100).

The counter circuit 1100 may also determine if the next first active command is provided on a first phase or a second phase. This may be determined based on if the count of operations on a given line (e.g., the value value0 provided on the terminal value_in) is even or odd. Whether the value is even or odd may be determined based on the least significant bit (LSB) of the value, when it is represented as a binary number. If the LSB is a 0, then it may represent an even value, and if it is 1 it may represent an odd value.

The received input value may be provided to a logic block 1106, which acts to strip the LSB from the received input value. For example, if the input value is nine (e.g., 1001), then the logic block 1106 provides a value of one. The LSB block 1114 stores a value of the LSB of the received value. The stored LSB may also be feedback to the other terminal of the multiplexer 1110 to maintain the stored LSB when the update value is inactive. The stored LSB may also be provided by the LSB block 1114 to the output terminal lsb (e.g., as the signal com0_ph.

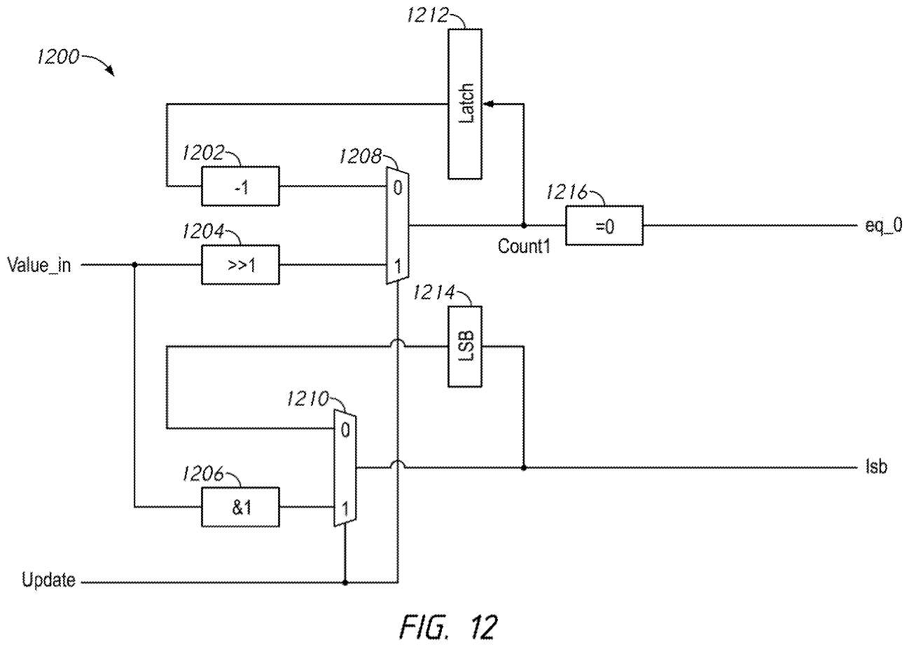

FIG. 12 is a block diagram of a counter circuit according to some embodiments of the present disclosure. The counter circuit 1200 may, in some embodiments, be included in the second counter circuit 1012 of FIG. 10. The counter circuit 1200 may generally be similar to the counter circuit 1100 of FIG. 11. For the sake of brevity, components and functionality described with respect to the counter circuit 1100 of FIG. 11 will not be repeated with respect to the counter circuit 1200 of FIG. 12.

In the counter circuit 1200, the latch circuit 1212 has an input terminal coupled in common to the input terminal of the comparator 1216. Accordingly, the multiplexer provides the value count1 to both the latch 1212 and the comparator 1216. Thus, the comparator 1216 may determine if the decremented value count1 is equal to 0, rather than determining if the stored value is equal to 0. In a similar fashion, the LSB block 1214 has an input terminal coupled in common to the terminal lsb. The counter circuit 1200 may set a value of eq_0 based on a current value of the latch 1212 count1, instead of a previous value of the latch such as the count0 of FIG. 11.

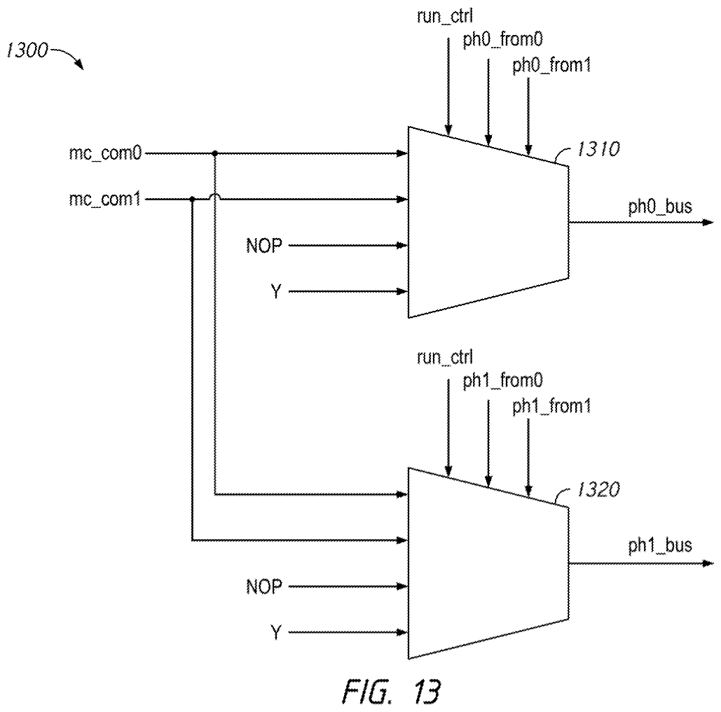

FIG. 13 is a block diagram of a command mixer according to some embodiments of the present disclosure. The command mixer 1300 may, in some embodiments, be included in the command mixer 912 of FIG. 9. The command mixer 1300 may generally be analogous to the command mixer 412 of FIG. 4, except that the command mixer 1300 provides a first phase bus signal ph0_bus and a second phase bus signal ph1_bus.

The command mixer 1300 may include a first phase mixer 1310 which provides the first phase bus signal ph0_bus and a second phase mixer 1320 which provides the second phase bus signal ph1_bus. The first phase mixer 1310 may determine a state of the signal ph0_bus by selecting one of the inputs mc_com0, mc_com1, NOP, and Y to provide as the signal ph0_bus. The first phase mixer 1310 may select one of the input signals based on the states of the signals run_ctrl, ph0_from0, and ph0_from1. An example logic table for the operation of the first phase mixer 1310 is given in Table 5, below. In a similar manner, the second phase mixer 1320 may select which of the inputs mc_com0, mc_com1, NOP, and Y to provide as the signal ph1_bus based on the states of the signals run_ctrl, ph1_from0, and ph1_from1. An example logic table for the operation of the second phase mixer 1320 is given in Table 6, below.

TABLE 5
Logic Table for First Phase Mixer

| run_ctrl | ph0_from0 | ph0_from1 | ph0_bus |
|---|---|---|---|
| 0 | x | x | Y |
| 1 | 0 | 0 | NOP |
| 1 | 1 | 0 | mc_com0 |
| 1 | 0 | 1 | mc_com1 |

TABLE 6
Logic Table for Second Phase Mixer

| run_ctrl | ph1_from0 | ph1_from1 | ph1_bus |
|---|---|---|---|
| 0 | x | x | Y |
| 1 | 0 | 0 | NOP |
| 1 | 1 | 0 | mc_com0 |
| 1 | 0 | 1 | mc_com1 |

As may be seen from Tables 5 and 6 above, when the enable signal run_ctrl is at a low logical level, then both the first and second phase mixers 1310 and 1320 provide the additional input signal Y as the phase bus signals ph0_bus and ph1_bus respectively. Responsive to signal run_ctrl being active (e.g., to enable to the operation of the APG), each of the phase mixers 1310 and 1320 may provide either an NOP command, the first active command mc_com0, or the second active command mc_com1.

The first phase mixer 1310 provides the NOP command as the signal ph0_bus when the signals ph0_from0 and ph1_from1 are both at a low level. When the signal ph0_from0 is at a high level (and ph0_from1 is at a low level), the first phase mixer 1310 provides the signal mc_com0 as the signal ph0_bus. When the signal ph0_from1 is at a high level (and the signal ph0_from0 is at a low level) then the first phase mixer 1310 provides the signal mc_com1 as the signal ph0_bus. The two phase mixers 1310 and 1320 may operate in a generally similar manner, except that the second phase mixer 1320 receives the signals ph1_from0 and ph1_from1 instead of the signals ph0_from0 and ph0_from1 respectively.

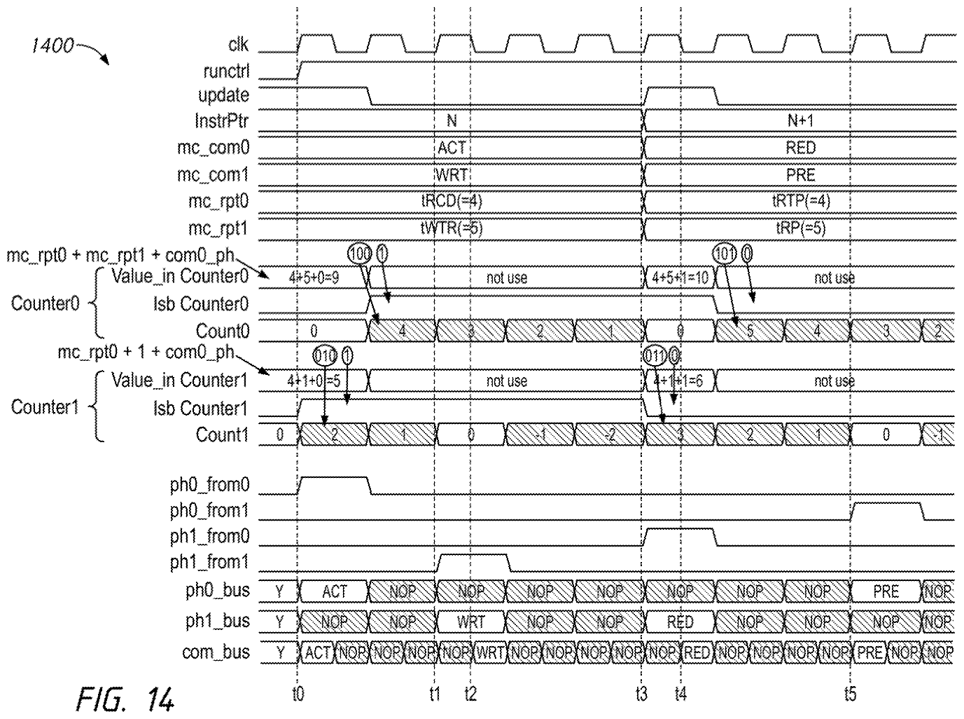

FIG. 14 is a timing diagram of an example operation of a multi-phase algorithmic pattern generator according to some embodiments of the present disclosure. In some embodiments, the timing diagram 1400 may represent the operation of an APG, such as the APG 900 of FIG. 9. The timing diagram 1400 may be similar to the timing diagram 800, except that the timing diagram 1400 describes a multi-phase APG. For the sake of brevity, features in the timing diagram 1400 similar to those in the timing diagram 900 will not be described again.

The timing diagram 1400 shows the operation of a multi-phase APG which responds to a first phase of a clock signal clk and a second phase of the clock signal clk. The APG may be loaded with a set of example instructions as shown in Table 7 below. The instructions in table 7 below produce the same expected output of the signal com_bus as the example instructions of Table 2, except that the example instructions in Table 7 are operated twice as fast, and include two active commands and NOP repeat values per line of instruction.

TABLE 7
Example Multi-Phase Instructions Loaded into APG

| Line Number | Control Instruction | Command Instruction | Expected Output |
|---|---|---|---|
| N | [ ] | ACT, NOPrpt(tRCD) | ACT, NOP, NOP . . . |
| | | | (ACT + NOP tRCD times) |
| | | WRT, NOPrpt(tWTR) | WRT, NOP, NOP, . . . |
| | | | (WRT + NOP tWTR times) |
| N + 1 | [ ] | RED, NOPrpt(tRTP) | RED, NOP, NOP . . . |
| | | | (WRT + NOP tRTP times) |
| | | PRE, NOPrpt(tRP) | PRE, NOP, NOP, . . . |
| | | | (PRE + NOP tRP times) |

At an initial time t0, the enable signal run_ctrl rises to a high logical level. The instruction pointer is indicating the line N, and accordingly the first active command (ACT) and second active command (WRT) are being provided as the signals mc_com0 and mc_com1 respectively. Similarly, the first and second NOP repeat values tRCD and tWTR are provided as the values mc_rpt0 and mc_rpt1. In this particular example, a value of four is used for tRCD and five is used for tWTR, although it should be understood that other values may be used in other embodiments.

At the initial time t0, the value count0 stored in the first counter circuit (e.g., 1199 of FIG. 11) is initialized to 0. The input to the first count value (e.g., value0 of FIG. 10) is 9, based on a sum of the two NOP repeat values mc_rpt0 and mc_rpt1 and the phase information com0_ph (e.g., 4+5+0=9). In binary, the value nine may be represented as 1001, and so the bit shifter may provide a value of four (e.g., 100) to be stored as the count value count0 on the next rising clock edge, and a value of 1 as the LSB. The stored value count0 and the value of LSB do not change until a next clock cycle after the clock cycle that begins at t0.

At the initial time t0, the value count) of the second counter changes. The input value of the second counter is an incremented value of the first NOP repeat value and the phase information (e.g., mc_rpt0+1+com0_ph=4+1+0=5). The bit shifter may provide a value of two (e.g., 010) and the LSB may be one. Since the second counter circuit responds to a current value on the input terminal, the values of count1 and LSB of the second counter may change at the time t0.

At the time t0, based on the signals ph0_from0 to ph1_from1, the value of the first phase bus is ACT (e.g., the first active command), while the value of the second phase bus is NOP. Accordingly, the output signal com_bus includes ACT at a first phase of the clock signal followed by NOP. Two more NOPs follow during the next clock cycle, as all of the signals ph0_from0 to ph1_from1 fall to a low logical level. At a time t1, the signal ph1_from1 rises to a high logical level, which causes the signal on the second phase bus ph1_bus to become WRT (e.g., the second active command). Accordingly, at t1 on the rising edge of the clock signal, the value of the first phase bus (e.g., NOP) is provided, followed at time t2 by the value of the second phase bus (e.g., WRT). As may be seen at time t0, the values of the output signal were ACT followed by NOP tRCD times.

In a similar manner, starting at time t2, the command WRT may be issued, followed by tWTR (e.g., five) NOP commands. At a time t4, line N of the instructions may be done executing. However, it took an odd number of clock phases (e.g., 11) to provide the commands based on line N of the instructions. Accordingly, the commands of line N+1 should be issued starting on a second clock phase (e.g., the falling edge). In order to manage the timing, at a time t3, on the first clock phase of the same clock cycle as the time t4, the signal ph1_from0 rises to a high logical level. The signal com0_en may also be at a high level (e.g., to indicate that the first active command is to be provided) which may cause the instruction pointer to update to the value N+1. In turn, this causes the value of the first and second active command to update to RED and PRE respectively, and the values tRTP (e.g., four) and tRP (e.g., five) to be loaded into the first and second counters respectively.

This causes the signal NOP to be provided as the first phase bus signal ph0_bus, while the first active command (e.g., RED) is provided as the second phase bus signal ph1_bus. Thus, at a first phase of the clock signal at t3, an NOP command is provided as the output com_bus to complete the execution of line N, while at t4 on the second phase of the clock cycle the command RED is provided as the signal com_bus to begin the execution of line N+1. The operation of the APG may continue to time t5, when the signal ph0_from1 rises to a high level to cause the signal PRE to be provided.

Although the present disclosure may generally be described with respect to using an APG as part of a built-in self-test (BIST) circuit used to perform a testing operation on a memory, it should be understood that the in-line NOP repeat commands and/or APG's of the present disclosure may be used with any set of instructions in many different kinds of semiconductor device. Similarly, although the example memories described herein are generally described as high bandwidth memories (HBMs), when the features of the present disclosure are used with a memory device, any type of memory device may be used.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
an algorithmic pattern generator (APG) circuit configured to execute a selected line of a plurality of instructions, wherein the APG circuit includes an instruction storage configured to store a control instruction portion of the selected line of the plurality of instructions and a command storage configured to store a command instruction portion of the selected line of the plurality of instructions, wherein the command instruction portion includes an active command and a no-operation (NOP) repeat command,
wherein the APG circuit is configured to provide the active command followed by a number of no-operation commands based on the no-operation repeat command.

2. The apparatus of claim 1, wherein the command storage is configured to store a value associated with the NOP repeat command, wherein the value indicates the number of times the NOP command is performed after the active command.

3. The apparatus of claim 1, wherein the APG is configured to select the selected line of the plurality of instructions based on the control instruction portion.

4. The apparatus of claim 1, wherein the APG circuit is configured to provide commands to a command bus with timing based on a clock signal.

5. The apparatus of claim 4, wherein the APG circuit is configured to provide a first command on a first phase of the clock signal and a second command on a second phase of the clock signal.

6. The apparatus of claim 1, wherein the command instruction portion is further configured to store a second active command and a second NOP repeat command of the selected line of the plurality of instructions.

7. The apparatus of claim 1, wherein the APG circuit is configured to provide a sequence of test commands to a memory array of a memory.

8. The apparatus of claim 7, wherein the memory is a high bandwidth memory including an interface die and a plurality of core dies, and wherein the APG circuit is included in the interface die and configured to provide the sequence of test commands to the memory array of at least one of the plurality of core dies.

9. An apparatus comprising:
a command storage configured to store an active command and a no-operation (NOP) repeat command value associated with a selected line of instruction;
an NOP controller circuit configured to provide a command enable signal at an active level responsive to a first time a clock signal is received and then provide the command signal at an inactive level a next number of times the clock signal is received, wherein the next number of times is based on the NOP repeat command value; and
a command mixer configured to provide the active command responsive to the command enable signal at the active level and provide a NOP command responsive to the command enable signal at the inactive level.

10. The apparatus of claim 9, further comprising a sequencer configured to provide an instruction pointer, wherein the command storage selects the selected line of instruction based on the instruction pointer.

11. The apparatus of claim 10, wherein the NOP controller circuit is configured to provide an update signal, and wherein responsive to the update signal the sequencer updates a value of the instruction pointer.

12. The apparatus of claim 10, further comprising a control storage configured to store a control instruction portion associated the selected line of instructions, and wherein the sequencer is configured to determine a next value of the instruction pointer based, at least in part, on the control instruction portion.

13. The apparatus of claim 9, wherein the NOP controller includes a counter circuit configured to receive the NOP repeat command value and store the NOP repeat command value as a stored value responsive to an update signal at an active level.

14. The apparatus of claim 13, wherein the NOP controller is configured to change the stored count value responsive to each time the clock signal is received, and provide the update signal and the command enable signal at an active level responsive to a comparison of the count value to a threshold.

15. An apparatus comprising:
a command storage configured to store a plurality of lines of instruction, wherein each of the plurality of lines of instruction includes a first active command, a first no-operation (NOP) repeat value, a second active command, and a second NOP repeat value;
a sequencer configured to provide an instruction pointer which selects one of the plurality of lines of instruction, wherein the command storage provides the first active command, the first NOP repeat value, the second active command, and the second NOP repeat value from the selected line of instruction; and
a command mixer configured to receive a clock signal and provide a command responsive to each phase of the clock signal, wherein the command mixer is configured to provide the first active command, provide a NOP command a number of times based on the first NOP repeat value, provide the second active command, and provide the NOP command a number of times based on the second NOP repeat value,
wherein after the NOP command is provided the number of times based on the second NOP repeat value, the sequencer is configured to change the instruction pointer to select a next one of the plurality of lines of instruction.

16. The apparatus of claim 15, wherein the clock signal includes a first phase which is a rising edge of the clock signal and a second phase which is a falling edge of the clock signal, and wherein the command mixer is configured to provide a command responsive to the rising edge of the clock signal and the falling edge of the clock signal.

17. The apparatus of claim 15, further comprising a phase controller circuit configured to receive the first NOP repeat value and the second NOP repeat value and provide a set of command signals to the command mixer, wherein the set of command signals includes a first command signal, a second command signal, a third command signal, and a fourth command signal.

18. The apparatus of claim 17, wherein the phase controller is configured to provide an update signal at an active state when the first command signal is in an active state, and wherein responsive to the update signal at an active state, the sequencer is configured to change the instruction pointer.

19. The apparatus of claim 17 wherein the command mixer comprises:
a first phase mixer configured to provide an NOP command, the first active command, or the second active command as a first output signal based on the states of the first command signal and the second command signal; and
a second phase mixer configured to provide the NOP command, the first active command, or the second active command as a second output signal based on the states of the third command signal and the fourth command signal.

20. The apparatus of claim 19, further comprising a serializer configured to provide the first output signal responsive to a first phase of the clock signal and the second output signal responsive to a second phase of the clock signal.

20. The apparatus of claim 15, further comprising a control storage configured to store a plurality of control instruction portions each associated with one of the plurality of lines of instructions, and wherein the sequencer is configured to determine the next one of the plurality of lines of instruction based, at least in part, on the control instruction portion of the selected one of the plurality of lines of instructions.

22. An apparatus comprising:
a controller configured to provide a plurality of lines of instructions to an algorithmic pattern generator (APG), wherein each of the plurality of lines of instructions includes:
a control instruction portion; and
a command instruction portion including an active command and a no-operation (NOP) repeat value,
wherein responsive to executing a selected one of the plurality of lines of instructions, the APG is configured to perform the active command and then issue a NOP command a number of times based on the NOP repeat value of the command instruction portion of the selected one of the plurality of lines of instruction.

23. The apparatus of claim 22, wherein the command instruction portion of each of the plurality of lines of instructions further includes a second active command and a second NOP repeat value.

24. The apparatus of claim 23, wherein responsive to executing the selected one of the plurality of lines of instructions the APG is configured to provide the active command, a number of the NOP commands based on the NOP repeat value, the second active command, and a second number of the NOP commands based on the second NOP repeat value.

25. The apparatus of claim 22, wherein the APG is configured to store the control instruction portion in a control storage and store the command instruction portion in a command storage.

26. The apparatus of claim 22, wherein after executing the selected one of the plurality of lines of instructions, the APG is configured to execute a next one of the plurality of lines of instructions based, at least in part, on the control instruction portion associated with the selected one of the plurality of lines of instructions.
